(19) United States
(12) Patent Application Publication
(10) Pub. No.: US 2020/0205288 A1
(43) Pub. Date: Jun. 25, 2020

(54) DISPLAY DEVICE AND ELECTRONIC APPARATUS

(71) Applicant: SHARP KABUSHIKI KAISHA, Sakai City (JP)

(72) Inventor: YOHICHI TAKAZANE, Sakai City (JP)

(21) Appl. No.: 16/721,812

(22) Filed: Dec. 19, 2019

(30) Foreign Application Priority Data
Dec. 20, 2018 (JP) 2018-238953

(51) Int. Cl. H05K 1/14; H05K 5/00

(52) U.S. Cl. CPC H05K 1/147; H05K 2201/10128; H05K 2201/055; H05K 5/0017

(57) ABSTRACT

A display device included in an electronic apparatus includes a display unit convexly curved toward the outside of a housing of the electronic device and a substrate disposed closer to the inside of the housing than the display unit and mounted with a drive circuit for driving the display unit. A spacer for fixing the substrate with respect to the display unit is disposed between the display unit and the substrate.

### BACKGROUND

### 1. Field

The present disclosure relates to a display device and an electronic apparatus.

### 2. Description of the Related Art

Japanese Unexamined Patent Application Publication No. 2007-79133 (published on Mar. 29, 2007) discloses a display module whose frame dimensions can be made smaller and whose thickness can be reduced. The display module includes a display panel of a planar shape, and has a flexible substrate (FPC) disposed to face the display panel and provided with a drive circuit, for driving the display panel.

According to the technology described in Japanese Unexamined Patent Application Publication No. 2007-79133 (published on Mar. 29, 2007, the FPC is fixed in surface contact with the display panel, as the shape of the display panel is a planar shape. However, in a case where the shape of the display panel is a curved surface shape, the FPC is fixed in contact with the display panel only at a plurality of points. Moreover, since the FPC is fixed in contact with the display panel only at the plurality of points, stress is applied to a particular position on the FPC, with the result that stress is applied to a particular position on the drive circuit provided on the FPC. Alternatively, since the display panel has a shape convexly curved toward the outside of a housing, the FPC may be deformed into a shape which conforms to that of the display panel, whereby stress is applied to a particular position on the drive circuit. This may result in damage to the drive circuit.

It is desirable to achieve a display device and the like whose drive circuit can be prevented from getting damaged.

### SUMMARY

According to an aspect of the disclosure, there is provided a display device included in an electronic apparatus, the display) device including: a display unit convexly curved toward an outside of a housing of the electronic device; and a substrate disposed closer to an inside of the housing than the display unit and mounted with a drive circuit for driving the display unit, wherein a spacer for fixing the substrate with respect to the display unit is disposed between the display unit and the substrate.

According to an aspect of the disclosure, there is provided an electronic apparatus including at least one display device, wherein the display device includes a display unit convexly curved toward an outside of a housing of the electronic device, and a substrate disposed closer to an inside of the housing than the display unit and mounted with a drive circuit for driving the display unit, and a spacer for fixing the substrate with respect to the display unit is disposed between the display unit and the substrate.

### Advantageous Effects of Invention

An aspect of the disclosure advantageously prevent a drive circuit from getting damaged.

### BRIEF DESCRIPTION OF THE DRAWINGS

FIG. 1 is a schematic view schematically showing a configuration of an electronic apparatus according to an embodiment of the present disclosure;

FIG. 2 is a schematic view schematically showing a configuration of a display device according to the embodiment of the present disclosure; and

FIG. 3 is a schematic view schematically showing a configuration of a modification of the display device according to the embodiment of the present disclosure.

### DESCRIPTION OF THE EMBODIMENTS

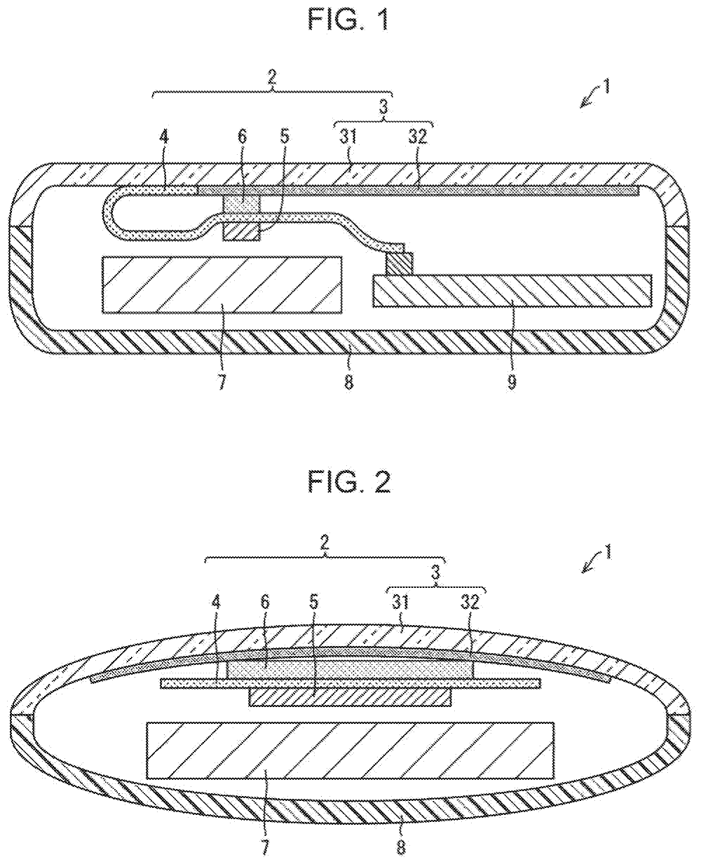

An embodiment of the present disclosure is described in detail with reference to FIGS. 1 and 2. FIG. 1 is a schematic view of a cross-section of an example of an electronic apparatus according to the present embodiment, and FIG. 2 is a schematic view of a cross-section of an example of a display device according to the present embodiment. It should be noted that the display device according to the present embodiment is used in an electronic apparatus, such as a smartphone, whose display unit is convexly curved toward the outside of a housing of the electronic apparatus.

An electronic apparatus 1 according to the present embodiment includes a display device 2, a battery 7, a housing 8, and a control device 9. The battery 7, the housing 8, and the control device 9 are not limited in number, performance, installation position, or the like.

### Display Device

The display device 2 includes a display unit 3, a substrate 4, a drive circuit 5, and a spacer 6.

### Display Unit

The display unit 3 has a shape convexly curved toward the outside of the housing 8 of a smartphone.

In the present embodiment, the display unit 3 includes a cover glass 31 and a display panel 32. Alternatively, the display unit 3 does not need to include the cover glass 31.

FIG. 2 illustrates a case where the display unit 3 included is a combination of the cover glass 31 and a display panel shaped in a single layer of convexity as a convex display panel 32. Alternatively, the convex display panel 32 may be a display panel shaped in multiple convexities. Specifically, the convex display panel 32 may be an OLED or a liquid crystal display.

### Substrate

The substrate 4 is disposed closer to the inside of the housing 8 than the display unit 3. Moreover, the substrate 4 is a substrate mounted with the after-mentioned drive circuit 5 on a surface of the substrate 4 that faces the battery 7. FIG. 1 illustrates a case where the substrate 4 is a flexible printed circuit board (also referred to as “FPC”). However, the substrate 4 is not limited to an FPC as long as the substrate 4 is a substrate on which the after-mentioned drive circuit 5 is placed.

### Drive Circuit

The drive circuit 5 is not limited to any particular circuit, and may be a circuit, such as a driver IC, for driving the display unit 3 that is placed on the surface of the substrate 4 that faces the battery 7. Of course, the drive circuit 5 may be placed behind the surface of the substrate 4 that faces the battery 7.

### Spacer

The spacer 6 is formed by an elastic material. A specific example of the elastic material by which the space 6 can be formed is a double-sided tape whose base material is PET, a PET-containing cushioning material, or the like. The spacer 6 is disposed between the display unit 3 and the substrate 4, and fixes the substrate 4 with respect to the display unit 3. For that purpose, the spacer 6 may fix the substrate 4 with respect to the display unit 3 by using an adhesive or the like on a surface of the spacer 6 that faces the display unit 3 and a surface of the spacer 6 that faces the substrate 4.

The spacer 6 is not limited in size or shape of the surfaces of the spacer 6 that face the display unit 3 and the substrate 4, respectively, as long as the spacer 6 can fix the substrate 4 with respect to the display unit 3.

In a case where the display unit 3 has a small curvature (i.e. in a case where the display unit 3 has an almost planar shape), a double-sided tape having adhesive properties on the surface of the spacer 6 that faces the display unit 3 and the surface of the spacer 6 that faces the substrate 4 may be used as an example of a shape of the spacer 6. Since the display unit 3 has an almost planar shape, the use of the double-sided tape as the spacer makes it possible to make it hard for the substrate 4 to be affected by the convex shape of the display unit 3, as the double-sided tape serving as the spacer 6 deforms.

On the other hand, in a case where the display unit 3 has a large curvature (i.e. in a case where the display unit 3 is greatly convexly curved toward the outside of the housing 8), use of a double-sided tape as the spacer 6 causes the spacer 6 to deform in conformance with the shape of the display unit 3 convexly curved toward the outside of the housing 8. Moreover, the contact of the spacer 6 with the substrate 4 at a plurality of points causes stress to be applied to a particular position on the substrate 4, so that stress concentrates on a particular position on the drive circuit 5. This may result in damage to the drive circuit 5.

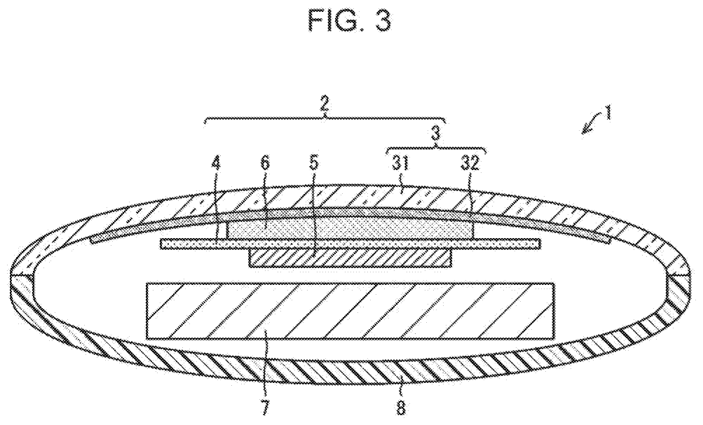

Accordingly, in a case where the display unit 3 has a large curvature, it is preferable that the spacer 6 be an elastic plate-like member having a thickness corresponding to the distance between the display unit 3 and the substrate 4 (see FIG. 3). As shown in FIG. 3, the shape of the spacer 6 of the present modification is different from the shape of the spacer 6 shown in FIG. 2.

For example, the surface of the spacer 6 that faces the display unit 3 has a shape having a curvature corresponding to that of the shape of the display unit 3, and the surface of the spacer 6 that faces the substrate 4 has a planar shape.

Since the spacer 6 is an elastic plate-like member having a thickness corresponding to the distance between the display unit 3 and the substrate 4, the curved shape of the display unit 3 is absorbed near the surface of the spacer that faces the display unit 3 and deformation of the surface of the spacer 6 that faces the substrate 4 is reduced, whereby the spacer 6 is easily brought into surface contact with the substrate 4. In an alternative configuration, the surface of the spacer 6 that faces the display unit 3 may be shaped to have a curvature corresponding to that of the shape of the display unit 3 and the surface of the spacer 6 that faces the substrate 4 may be shaped into a flat surface, so that the surface of the spacer 6 that makes contact with the substrate 4 may be a flat surface. Such a configuration prevents stress from concentrating on a particular site on the drive circuit 5 placed on the substrate 4. As a result, damage to the drive circuit 5 due to stress concentration can be reduced.

The present disclosure is not limited to any of the embodiments described above but may be altered in various ways within the scope of the claims, and an embodiment based on a proper combination of technical means disclosed in different embodiments is encompassed in the technical scope of the present disclosure. Furthermore, a new technical feature can be formed by a combination of technical means respectively disclosed in embodiments.

### Conclusion

A display device (2) according Aspect 1 of the present disclosure is a display device (2) including: a display unit (3) convexly curved toward an outside of a housing (8) of the electronic device (1); and a substrate (4) disposed closer to an inside of the housing (8) than the display unit (3) and mounted with a drive circuit (5) for driving the display unit (3), wherein a spacer (6) for fixing the substrate (4) with respect to the display unit (3) is disposed between the display unit (3) and the substrate (4).

According to the foregoing configuration, the fixing of the substrate (4) to the display unit (3) by the spacer (6) prevents stress from concentrating on a particular site on the substrate (4) and makes it possible to reduce damage to the drive circuit (5).

Aspect 2 of the present disclosure may be directed to the display device (2) according to Aspect 1, wherein the spacer (6) is formed by an elastic material.

According to the foregoing configuration, the formation of the spacer (6) by the elastic material causes the spacer (6) to make surface contact with the display unit (3) and the substrate (4). This prevents stress from concentrating on a particular site on the substrate (4) and makes it possible to reduce damage to the drive circuit (5).

Aspect 3 of the present disclosure may be directed to the display device (2) according to Aspect 1 or 2, wherein a surface of the spacer (6) that faces the display unit (3) has a shape having a curvature corresponding to that of a shape of the display unit (3).

According to the foregoing configuration, the surface of the spacer (6) that faces the display unit (3) is curved in conformance with the shape of the display unit (3), so that the spacer (6) more easily makes surface contact with the display unit (3) and the substrate (4).

An electronic apparatus (1) according to Aspect 4 of the present disclosure is an electronic apparatus (1) including at least one display device (2), wherein the display device (2) includes a display unit (3) convexly curved toward an outside of a housing (8) of the electronic device (1), and a substrate (4) disposed closer to an inside of the housing (8) than the display unit (3) and mounted with a drive circuit (5) for driving the display unit (3), and a spacer (6) for fixing the substrate (4) with respect. to the display unit (3) is disposed between the display unit (3) and the substrate (4).

The foregoing configuration makes it possible to reduce damage to the drive circuit (5).

The present disclosure contains subject matter related to that disclosed in Japanese Priority Patent Application JP 2018-238953 filed in the Japan Patent Office on Dec. 20, 2018, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device included in an electronic apparatus, the display device comprising:
a display unit convexly curved toward an outside of a housing of the electronic device; and
a substrate disposed closer to an inside of the housing than the display unit and mounted with a drive circuit for driving the display unit,
wherein a spacer for fixing the substrate with respect to the display unit is disposed between the display unit and the substrate.

2. The display device according to claim 1, wherein the spacer is formed by an elastic material.

3. The display device according to claim 1, wherein a surface of the spacer that faces the display unit has a shape having a curvature corresponding to that of a shape of the display unit.

4. An electronic apparatus comprising at least one display device,
wherein the display device includes
a display unit convexly curved toward an outside of a housing of the electronic device, and
a substrate disposed closer to an inside of the housing than the display unit and mounted with a drive circuit for driving the display unit, and
a spacer for fixing the substrate with respect to the display unit is disposed between the display unit and the substrate.
